(19) United States
(12) Patent Application Publication
(10) Pub. No.: US 2007/0114123 A1
(43) Pub. Date: May 24, 2007

(54) Deposition on charge sensitive materials with ion beam deposition

(76) Inventor: Jeffrey Bender, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/285,222

(22) Filed: Nov. 21, 2005

(51) Int. Cl. C23C 14/00

(52) U.S. Cl. 204/192.12

(57) ABSTRACT

A method is described that involves applying a first voltage to a first mesh located above a wafer. The wafer has a charge sensitive material exposed thereon. The method also involves applying a second voltage to a second mesh located above the wafer. The method also involves depositing a layer of material by ion beam deposition onto the charge sensitive material while the voltages are applied to their respective meshes.

### FIELD OF INVENTION

The field of invention relates generally to the semiconductor arts, and, more specifically, deposition on charge sensitive materials with ion beam deposition.

### BACKGROUND

Ion beam deposition is a deposition technique that directs a high energy ion beam toward a target made of material to be sputter deposited onto a wafer (e.g., a semiconductor wafer having features pattered thereon that help form a plurality of electronic semiconductor chips). A simplistic depiction of an ion beam deposition system is presented in FIG. 1.

According to the depiction of FIG. 1, a deposition chamber 100 is coupled to an ion source component 101. The deposition chamber 100 also includes a target 102 and a wafer 103. A plasma is formed within the ion source component 101. The plasma's constituent atoms (e.g., Argon (Ar) atoms or Xenon (Xe) atoms) and electrons collide with one another causing at least some of these atoms to lose one or more electrons such that they become positively charged ions. The positively charged ions are extracted from the ion source component 101, formed into a beam 104 and directed to a target 102. The target 102 is made of material which is to be deposited onto the wafer 103. When the ion beam's ions collide with the target 102, the target's constituent atoms are knocked off the target 102. These atoms then deposit on the wafer 103 such that a film of the target material is formed on the wafer 103.

Unfortunately, if ion beam deposition is used to deposit target material onto a “charge sensitive” material (such as a ferroelectric polymer exposed on the surface of the wafer), the charge sensitive material is observed to be “degraded” after the ion beam deposition process is performed. Ion beam deposition has therefore not gained acceptance as a legitimate deposition technique for deposition onto charge sensitive materials. Alternative deposition techniques, such as thermal evaporation, are therefore used to deposit onto charge-sensitive materials even though ion bean deposition is capable of providing higher quality deposited films (e.g., in terms of defects in film microstructure) than these alternative deposition techniques.

### BRIEF DESCRIPTION OF THE DRAWINGS

The present invention is illustrated by way of example and not limitation in the figures of the accompanying drawings, in which like references indicate similar elements and in which:

FIG. 1 (prior art) shows an ion beam deposition system;

FIG. 2 shows a wafer and a region just above the wafer;

FIGS. 3a and 3b show a sub-chamber assembly for use within an ion beam deposition system;

FIG. 4 shows detected charge in a region just above a wafer as a function of voltage applied to the upper and lower meshes depicted on FIGS. 3a and 3b;

FIG. 5 shows an ion beam deposition system that includes the sub-chamber assembly depicted in FIGS. 3a and 3b.

### DETAILED DESCRIPTION

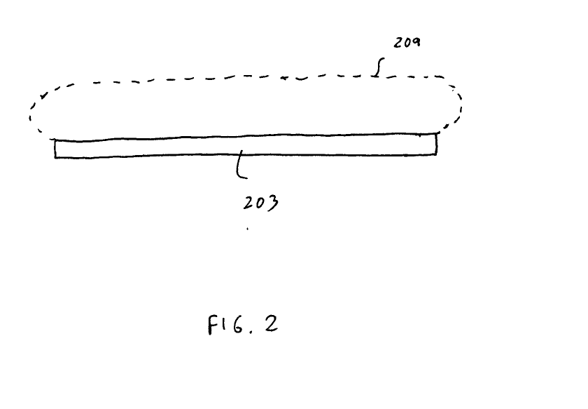

In order to address the issues associated with ion beam deposition onto “charge sensitive” materials, the dynamics of ion beam deposition and its effects on a charge sensitive material should be better understood. FIG. 2 shows a wafer 203 that may be assumed to have an exposed layer of charge sensitive material on its surface. Here, a charge sensitive material can be assumed to be a material that structurally decomposes in the presence of electrically charged particles (e.g., positively charged ions or negatively charged electrons). For instance, a layer or trench of ferroelectric polymer can “unravel” in the presence of electrons and/or positively charged ions. Examples of charge sensitive materials other than ferroelectric polymers include various plastics or other materials containing organic bonds that are sensitive to plasma damage (e.g., including low-K dielectrics now that incorporate organic material into SiO2 to lower the dielectric constant).

Note that plasma exposure is routinely used to promote adhesion on plastics such as polyimide, polypropylene, etc.—adhesion improves because the plastic is ripped apart at the surface and therefore better able to form new chemical bonds with a material. With respect to the deposition of insulating materials (tantalum oxide, silicon oxide, calcium fluoride, etc.), if the growing film is bombarded with charged particles it builds up a charge and therefore a potential. Once the dielectric strength of the film is exceeded a breakdown occurs, which destroys an area of the film. Usually in these sorts of applications particles of the opposite polarity are purposely introduced to the system to cancel the charge so that no potential develops.

The most basic dynamic process of ion beam deposition involves the deposition of “charge neutral” target atoms onto the surface of the wafer 203. That is, impingement of the ion beam with the target creates a number of “intact” atoms that have neither lost electron(s) nor gained electron(s) and are therefore electrically neutral as they deposit onto the surface of the wafer 203. Deposition of these charge-neutral atoms is encouraged in the case of deposition onto charge sensitive materials because charge-neutral atoms are not believed to promote any electrical reaction with the charge sensitive material, and, as a consequence, no structural decomposition of the charge sensitive material should result.

The problematic correlation between the structural quality of the charge sensitive material being deposited upon and the ion beam deposition process is believed to be related to the abundance of charged particles (most notably, positively charged ions and negatively charged electrons) that exist just above the surface of the wafer 203 (e.g., in region 209) during deposition. Essentially, the ion beam deposition process naturally lends itself to the creation of not only charge-neutral target atoms within the deposition chamber as described just above, but also, positively charged ions and negatively charged electrons. These charged particles are capable of being present just above the wafer during the deposition process such that a charge sensitive material that is being deposited upon electrically reacts with these charged particles thereby causing its structural decomposition.

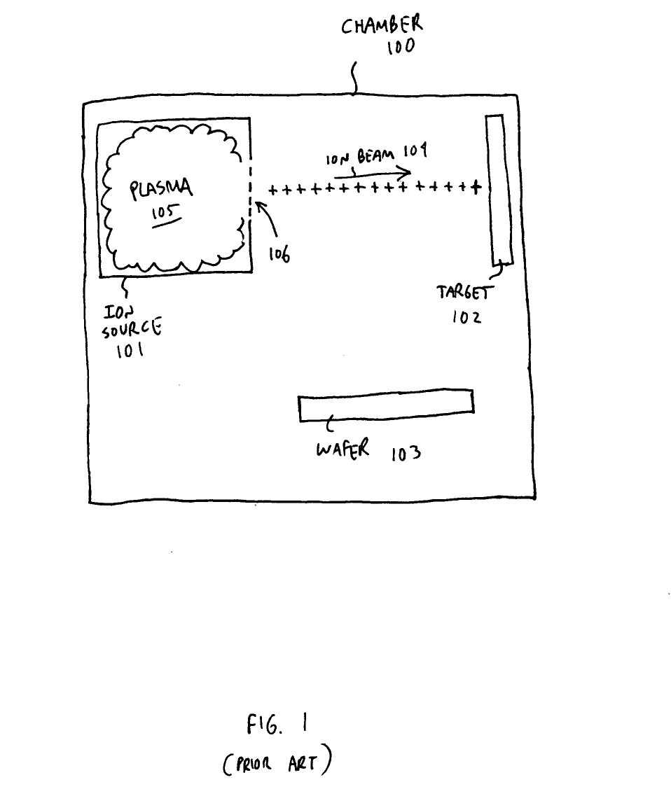

Referring back to FIG. 1, some ion beam deposition dynamics believed to cause the creation of these undesirable charged particles include: 1) emission of electrons from the plasma 105 into the deposition chamber 102 (e.g., through the ion source component's “porous” interface 106 with the deposition chamber 100); 2) emission of secondary electrons from the chamber's background gas atoms and/or target atoms and/or ion beam ions (e.g., resulting from high energy atomic collisions); 3) charge transfer the ion beam's 104 ions and the deposition chamber's background gas atoms (specifically, if a background gas atom passes near the ion beam 104, an electron from the background gas atom may transfer to a positively charged ion in the ion beam leaving the background gas atom as a low energy positively charged ion); 4) positive ions of target material that are knocked off the target by the ion beam 104 (note that these ions may range from high to low energy depending on the specific collision dynamics of each); and, 5) electrons generated from item 4) just above.

Of the various ion beam deposition dynamics described above, note that categories 1), 2) and 5) may be deemed to create “low energy” charged particles because they create electrons. Here, electrons may be regarded as possessing low kinetic energy. In the case of 1) the electron energy is low because the accelerating field the electron sees is the sheath of the ion source plasma (about 40 V or so), the ions on the other hand are purposely accelerated through 100s of volts (typically ˜1000-1500 V in ion beam deposition). 2) and 5) are essentially the same thing (secondaries) which are low-energy by nature (usually <50 eV). Also, note that category 3) above may be deemed to create a low energy charged particle because background gas atoms are not accelerated like the ions in the ion beam 104.

Thus, background gas atoms tend to drift in the deposition chamber 100 at much lower speeds than the ions in the ion beam 104 and therefore may also be deemed to posses low kinetic energy. Background gas atoms are typically inert atoms such as Ar or Xe. They may be separately added to the deposition chamber 100 and/or may diffuse into the chamber 100 from the plasma 105. Also, as indicated in the parenthetical comment following category 4), some percentage of the ionized target material atoms that exist in the chamber 100 may be low energy particles also.

Thus, of the ion beam deposition process dynamics categories listed above, particles created according to categories 1) through 3) and 5) and some percentage of category 4) correspond to the creation of low energy particles within the chamber 100. It therefore follows that a “not insignificant” percentage of the charged particles that reside within the deposition chamber 101, including those residing in region 209 of FIG. 2, are low energy particles rather than high energy particles.

Because a “not insignificant” percentage of the charged particles within region 209 are believed to be low energy particles, there exists some opportunity that they can be removed from the region 209 just above the surface of the wafer 203. If so, the result will be a less electrically reactive cloud just above the surface of the wafer 203 that, by its nature, will induce less electrical reaction with the charge sensitive material on the wafer 203 than otherwise would occur if no attempt to remove the low energy charged particles existed (as in prior art approaches). Because less electrical reaction is induced with the charge sensitive material, the removal of the low energy charged particles should result in the charge sensitive material suffering less structural degradation from the ion deposition process.

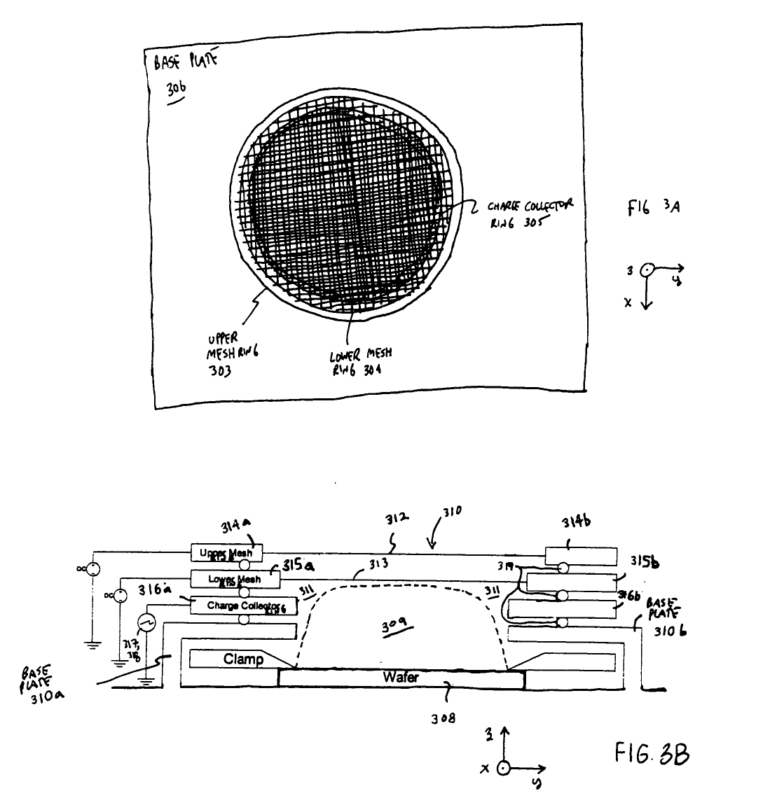

FIGS. 3a and 3b depict an apparatus for preventing low energy charged particles from migrating to the region 309 that exists just above the surface of the wafer 303. FIG. 3a shows a top view (looking down onto the wafer from above the wafer). FIG. 3b shows a cross sectional view. According to the approach depicted in FIGS. 3a and 3b, a base plate 310 and a stacked structure that includes mesh frames 314, 315 essentially forms a “sub-chamber” 311 that contains the region 309 just above the wafer 303 where the removal of charged particles is desired. Ideally, only particles that enter the sub chamber 311 through chamber opening 310 are capable of being deposited onto the wafer 303.

A first, upper mesh 312 is fixed approximately at the opening to the sub-chamber 311 such that a particle can enter the sub-chamber 311 (and deposit on the wafer 303) only if it flows through the upper mesh 312. An electrostatic potential (in one implementation, a DC voltage) is applied to the upper mesh 312. The electrostatic potential induces electric field lines that emanate from (or terminate on) the mesh 312 (depending on the polarity of the potential).

The electric field lines “affect” the motion of low energy charged particles that are moving toward the sub chamber 311 such that they are prevented from entering the sub-chamber 311. However, the electric field lines do not affect the motion of charge neutral particles that are moving toward the sub-chamber 311. Recalling the above discussion that it is desirable that charge neutral and not charged particles reside in the region 309 just above the wafer 303, note that the structure of FIGS. 3a and 3b has the desired affect of thwarting the flow of at least low energy charged particles toward region 309 but not thwarting the flow of charge neutral target atoms toward region 309.

A mesh structure is essentially any structure having an arrangement of openings (typically in a repetitive pattern). The specific embodiment of FIGS. 3a and 3b shows two mesh structures 312, 313, where, each mesh structure 312, 313 is made of a first plurality of electrically conductive wires that span across an opening to the sub chamber and a second plurality of electrically conductive wires that span across the same sub-chamber opening, where, the first plurality of wires and the second plurality of wires run perpendicular to one another (e.g., so that each mesh corresponds to a grid of openings formed with its respective wires). The meshes are each made of electrically conductive material such as a metal or metal alloy (e.g., stainless steel).

A first of the mesh structures is given a negative potential and a second of the mesh structures is given a positive potential (relative to the baseplate 310 and wafer 303 which are electrically grounded (i.e., 0 volts)). In a preferred implementation the higher mesh 312 is given a negative potential and the lower mesh 313 is given a positive potential.

In this case, the negative potential mesh 312 sinks (i.e., terminates) electric field lines which has the corresponding effect of repelling negatively charged electrons. The positive potential mesh 313 sources (i.e., emanates) electric field lines which has the corresponding effect of repelling positively charged particles (such as positively charged ions). In a further feature of the preferred implementation, the potential of the lower, positively charged mesh 313 has a higher absolute value than the higher, negatively charged mesh 312 (e.g., the positively charged mesh 313 has a positive potential in the hundreds of volts but the negatively charged mesh 312 has a negative potential in only the tens of volts). According to this design, electrons should be repelled from reaching region 309 before reaching the higher mesh 312 and positively charged particles should be repelled from reaching region 309 before reaching the lower mesh 313.

In an implementation where the sub-chamber 311 opening is circular, the meshes 312, 313 are secured in a circular frame (e.g., “rings” 314 and 315). Of course, other frame shapes are possible such as square or rectangular. The lower mesh 313 is electrically isolated from the baseplate 310 and the upper mesh 312 with beads or rings 319 made of electrically insulating material (e.g., a ceramic, quartz (glass), sapphire (ion source grid assemblies are typically insulated/spaced by sapphire balls), or a polymer such as polyimide.)

FIGS. 3a and 3b also show a third, lowest ring 316 that approximately encircles the region 309 just above the wafer 303 where only charge neutral particles are desired. In an implementation the lowest ring 316 does not support a mesh nor is set to a fixed potential by the deposition equipment. Rather, the lowest ring 316 is used as a device that measures the charge in region 309. Here, if a net positive charge is present in region 309, a voltmeter 317 that is coupled across ring 316 to ground should measure a positive voltage and an ammeter 318 should detect a current flow into ground. Contrariwise, if a net negative charge is present in region 309, the voltmeter 317 should measure a negative voltage and the ammeter 318 should detect a current flow from ground.

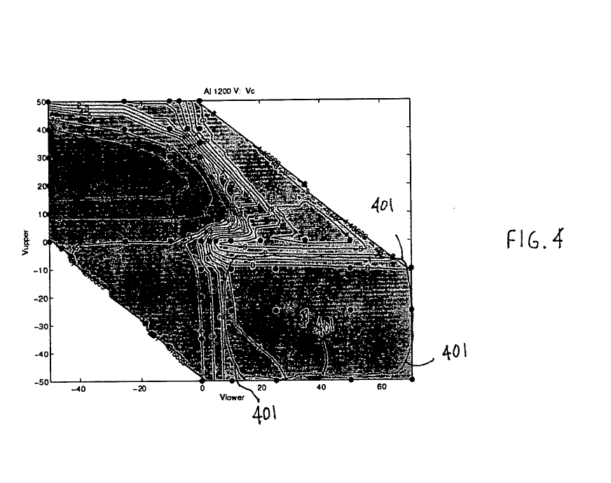

Ideally, no voltage is detected by the voltmeter 317 and no current is detected by the ammeter 318 signifying that the region 309 just above is free of charge. FIG. 4 plots the voltage detected by the voltmeter 317 across a range of applied voltage magnitudes and polarities to both the upper (Vᵤₚₚₑᵣ) and lower (V_{lower}) meshes for the following, exemplary, ion beam deposition conditions. For the plot shown, the conditions were: beam voltage =1200 V (thus the beam ions have ˜1200 eV of energy); suppressor voltage=150 V (this voltage keeps electrons from flowing back into the source and also controls the spread (focus) of the ion beam); rf power=600 W (ion source power); Ar gas flow=10 sccm through the ion source; target material=A1 (different materials will emit more or fewer secondary electrons and reflect/backscatter the beam at different energies and probabilities).

FIG. 4 shows a large operating region 401 where negligible charge is detected just above the wafer when a positive potential is applied to the upper mesh and a negative potential is applied to the lower mesh. Region 401 “extends” far to the right off the depicted scale in FIG. 4 (e.g., Vᵤₚₚₑᵣ>100 volts and 0>V_{lower}>−50 volts). According to one perspective, a large positive potential is applied to the lower mesh (e.g., in hundreds of volts such as 400 volts) and a smaller negative potential is applied to the upper mesh (e.g., in hundreds of volts such as −40 volts).

Referring back to FIG. 3b, the arrangement of potential in this fashion is believed to support the objective of keeping the region 309 just above the wafer 303 free of charged particles for the following reasons. Firstly, electrons, being essentially massless, are more easily kept from the sub chamber 311 with a “weaker” electric field such as an electric field produced from application of a potential to a mesh that is only in the tens of volts. As such, the application of a negative potential in the tens of volts to the upper mesh 312 forms a weak electric field above the upper mesh 312 that strongly repels electrons from the sub-chamber 311 and only weakly accelerates heavier positively charged ions toward the sub-chamber 311. Thus, it is believed that, according to this setup, for the most part, positive ions pass through the upper mesh 312 but electrons do not.

The placement of a positive voltage in the hundreds of volts to the lower mesh 312 in combination with keeping the distance between the upper and lower meshes relatively short (e.g., less than 1.0 centimeters such as 0.5 cm) provides for a much stronger electric field between the two meshes 312, 313 that repels positive ions from the region 309 just above the wafer. For instance, in an application where V_{lower}=+400 volts, Vᵤₚₚₑᵣ=−40 volts and the distance between the two meshes is 0.5 cm, the electric field strength between the two meshes 312, 313 is on the order of 440V/0.5 cm=880 V/cm. The much stronger field between the two meshes 312, 313 (as compared to the field strength above the upper mesh 312) is believed to be better able to prevent the penetration of heavier positive ions to the region just above the wafer 309. Additionally, in this application, the lower mesh 313 is 30cm above the wafer surface.

Referring back to FIG. 4, note that negligible charge is detected in regions other than those corresponding to V_{lower}<0 and Vᵤₚₚₑᵣ>0. As such, even though it appears that V_{lower}<0 and Vᵤₚₚₑᵣ>0 yield a wide operating range where little or no charge is observed above the wafer, nevertheless, it appears that other operating regions may be used outside the V_{lower}<0 and Vᵤₚₚₑᵣ>0 boundary. Note that the third, lower ring 316 need not be installed in an application where the physics within the chamber are well enough understood that detection of the charge within the region just above the wafer is not necessary.

Note that the use of the mesh apparatus should be better than neutralization techniques because charged particles are prevented from reaching the film in the first place (by contrast, with respect to neutralization techniques, film degradation occurs before charge can be neutralized). In applications where trapped charges in the growing film might be important (e.g., electrical insulators) it may be best to avoid introducing charges as much as possible rather than trying to neutralize them, the mesh apparatus is a potentially better solution.

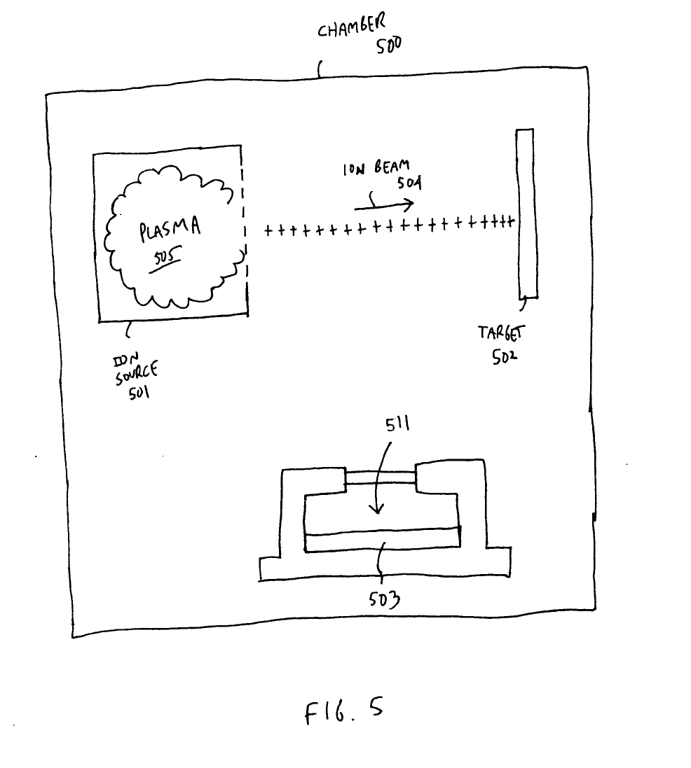

FIG. 5 shows an ion beam deposition system that includes a sub chamber designed according to the principles outlined above. According to the depiction of FIG. 5, a deposition chamber 500 is coupled to an ion source component 501. The deposition chamber 500 also includes a target 502 and a wafer 503. A plasma is formed within the ion source component 501. The plasma's constituent atoms (e.g., Argon (Ar) atoms or Xenon (Xe) atoms) and electrons collide within one another causing at least some of these atoms to lose one or more electrons such that they become positively charged ions. The positively charged ions are extracted from the ion source component 501, formed into a beam 504 and directed to a target 502. The target 502 is made of material which is to be deposited onto the wafer 503.

The wafer 503 has exposed on its surface a charge sensitive material. When the ion beam's ions collide with the target 502, the target's constituent atoms are knocked off the target 502. Some of these atoms are electrically neutral while others are positively ionized. Electrically neutral atoms flow largely uninhibited through the mesh structure into the sub chamber assembly 511 and deposit on the wafer 503 such that a film of the target material is formed on the wafer 503. The positively ionized atoms (as well as electrons) are repelled from the sub chamber assembly because voltages are applied to the meshes (with wiring) while the ion source is energized to produce an ion beam during sputter deposition.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. A method, comprising:
applying a first voltage to a first mesh located above a wafer, said wafer having a charge sensitive material exposed thereon;
applying a second voltage to a second mesh located above said wafer; and,
depositing a layer of material by ion beam deposition onto said charge sensitive material while said voltages are applied to their respective meshes.

2. The method of claim 1 wherein said first voltage is less than said wafer's voltage.

3. The method of claim 2 wherein said first voltage has an absolute value less than 100 volts.

4. The method of claim 2 wherein said second voltage is greater than said wafer's voltage.

5. The method of claim 4 wherein said second voltage has an absolute value less than 1000 volts.

6. The method of claim 1 wherein said depositing a layer of material by ion beam deposition comprises creating a plasma from Xe atoms.

7. The method of claim 1 wherein said depositing a layer of material by ion beam deposition comprises creating a plasma from Ar atoms.

8. The method of claim 1 wherein said method further comprises monitoring charge above said wafer.

9. An apparatus, comprising:
a) a wafer sub chamber for use within an ion beam deposition chamber, said wafer sub chamber having a first mesh that spans across a first surface area bounded by said wafer sub chamber's inner wall, said wafer sub chamber having a second mesh that spans across a second surface area bounded by said wafer sub chamber's inner wall;
b) a first voltage source coupled to said first mesh supply to apply a first voltage to said first mesh;
c) a second voltage source coupled to said second mesh to apply a second voltage to said second mesh.

10. The apparatus of claim 9 wherein said first mesh comprises wires running in different directions.

11. The apparatus of claim 10 wherein said wires are affixed to a frame that forms a segment of said wafer sub chamber.

12. The apparatus of claim 11 wherein said second mesh comprises wires running in different directions.

13. The apparatus of claim 12 wherein said second mesh's wires are affixed to a second frame that forms a second segment of said wafer sub chamber.

14. The apparatus of claim 13 wherein said first and second frames are separated by electrically insulating material that forms a third segment of said wafer sub chamber.

15. An ion beam deposition system, comprising:
a) an ion source;
b) a chamber
c) a wafer sub chamber for use within said chamber, said wafer sub chamber having a first mesh that spans across a first surface area bounded by said wafer sub chamber's inner wall, said wafer sub chamber having a second mesh that spans across a second surface area bounded by said wafer sub chamber's inner wall;
d) a first voltage source coupled to said first mesh supply to apply a first voltage to said first mesh;
e) a second voltage source coupled to said second mesh to apply a second voltage to said second mesh.

16. The apparatus of claim 15 wherein said first mesh comprises wires running in different directions.

17. The apparatus of claim 16 wherein said wires are affixed to a frame that forms a segment of said wafer sub chamber.

18. The apparatus of claim 17 wherein said second mesh comprises wires running in different directions.

19. The apparatus of claim 18 wherein said second mesh's wires are affixed to a second frame that forms a second segment of said wafer sub chamber.

20. The apparatus of claim 19 wherein said first and second frames are separated by electrically insulating material that forms a third segment of said wafer sub chamber.
